(19) United States
(12) Patent Application Publication
(10) Pub. No.: US 2022/0087046 A1
(43) Pub. Date: Mar. 17, 2022

(54) MODULARIZED FRONT WINDOW OF A SERVER SYSTEM

(71) Applicant: Quanta Computer Inc., Taoyuan City (TW)

(72) Inventors: YAW-TZORNG TSORNG, Taoyuan City (TW); TUNG-HSIEN WU, Taoyuan City (TW); SHIN-MING SU, Taoyuan City (TW); CHUNG-HAO HUANG, Taoyuan City (TW)

(21) Appl. No.: 17/023,759

(22) Filed: Sep. 17, 2020

(51) Int. Cl. H05K 7/14

(52) U.S. Cl. CPC H05K 7/1489

(57) ABSTRACT

Described herein are modular server systems. The server systems include a server chassis having one or more window bays each having the same dimensions. The system also includes a plurality of device trays each for holding a device that is selected from a plurality of different devices. Each device tray fits in the one or more window bays.

### TECHNICAL FIELD

The present disclosure relates generally to a modularized front window of a server system. More particularly, aspects of this disclosure relate to a unified chassis having front window bays with the same dimensions, and configured to accept one or more device trays, with each tray adapted for holding a different device type.

### BACKGROUND

Servers are specialized computer systems including numerous electronic components that are integrated in a single unit using a server chassis. For example, servers can be dedicated for storage, computation, or audio-visual media purposes. Such purposes often determine the components mounted in the server chassis. In addition, servers have evolved to having different form factors. An early design, still in use today, is a tower case. Rackmount servers were introduced after the tower design and, more recently, blade servers have been implemented. The rackmount server can be generally described as a rectangular box, where each server can be placed in a rack horizontally. This form factor offers advantages over a tower case in space savings, which generally require a table top or cabinet. Blade servers can provide additional space savings and can be useful, particularly where some components, such as power supplies and cooling fans, can be shared among different blade servers.

Although there are some non-standard sizes, server rack heights are classified by rack units “U” where one “U” is equal to 1.75 inches. The total rack heights can vary, for example, from as little as 4 U to 42 U. Rackmount servers are designed to fit into slots or racks of the server rack. The slot or rack height can be sub-divided into multiple “U” units to accommodate different server heights, such as 1 U, 2 U, 3 U, and 4 U. Other dimensions of the server rack are referred to by standard units, such as inches. A standard width of a server rack, for example, is 19 inches. Typically, servers range from 24 to 48 inches in depth. Some server racks are also designed to accommodate more than one type of server form factor (e.g., tower case, rackmount, and blade server). Peripherals, such as input/output devices (e.g., monitor, keyboard, mouse), clips for cable management, and the like, can also be accommodated by the server rack design.

The server rack therefore is designed to be modular, where different server sizes and form factors can be accommodated. This allows for the changing of servers mounted in a server rack for maintenance, or for the changing needs for a server system accommodating multiple servers. Although offering some flexibility, the standard systems do not provide modularization at the device level, as illustrated with reference to FIG. 1A and FIG. 1B.

FIG. 1A illustrates a front portion of a prior art rackmount server chassis 100 having window bays 102a to 102d. Window bays 102a, 102c, and 102d are shown with a device 104 in place in window bays 102a, 102c and 102d. Window bay 102b is open and has dimensions for accepting the device 104.

FIG. 1B shows the prior art server chassis 100 with window bay 102a to 102d open. A user, such as a technician, may desire placing a device, such as device 106, into one of these window bays, such as window bay 102b. However, the window bays 102a to 102d cannot accommodate the device 106 because it has dimensions different from the device 104. Therefore, a different chassis must be used for such a change.

With the current design, multiple chassis are needed when different devices are desired. An existing chassis cannot be easily re-purposed for a different use, such as from a memory storage server to a computation server. Likewise, an existing chassis cannot be easily augmented with an upgraded device, such as swapping a 3.5 inch Hard Disk Drive (HDD) with a 2.5 inch HDD or a Solid State Drive (SSD). When assembling a new server system, an inventory of different chassis types is therefore needed to accommodate using different components. Furthermore, a combination of components having different form factors, such as the devices 104 and 106, cannot be accommodated by a single chassis.

Thus, there is a need for a unified chassis system that can accommodate different types of devices. It would be desirable for the devices to be easy to interchange in the chassis and require no re-design. Such a system would provide improvements in cost and efficiency to server designs.

### SUMMARY

The term embodiment and like terms are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings and each claim.

A first implementation of the disclosure is a modular server system. The modular server system includes a server chassis having one or more window bays, with each having the same dimensions. This implementation also includes a plurality of device trays, each for holding a device. The device is selected from different devices, and each device tray fits in the one or more window bays.

Optionally, at least a first device selected from the plurality of devices has a form factor that is different from a form factor of a second device selected from the devices. Optionally, the device is a member of a group of devices, wherein each device in the group of devices have the same form factor. In some implementations, one device tray includes a device carrier for coupling a device with the device tray. The device is optionally selected from one or more of a hard disk drive (HDD), a solid state drive (SSD), a Graphics Processing Unit (GPU), and a ruler device.

In some implementations, the device tray comprises one or more device slots having interior surfaces defining an interior space for placement of the device. The device slots further include a front aperture for slide-in placement of the device; a back aperture for connecting the device to at least a second device; and a fastener for holding the device in the device slot. Optionally, the interior space is defined by a top interior surface, a bottom interior surface, and a spacer interior surface.

In some implementations of the system, the window bays include a window horizontal width about equal to a device tray width; a window vertical height about equal to a device tray height; and a window depth about equal to or less than the device tray depth. An aperture in the chassis is defined by the window horizontal width and window horizontal height. The aperture allows slide-in placement of the device trays in each of the window bays. Slide-in placement is by engagement of one or more of an inner surface of the widow bay, a rail of the window bay, a groove of the window bay, and a fastener. Optionally, the sever chassis includes a top cover which can be removed for placement of device trays in the window bays.

In some implementations of the modular server system, the server chassis includes a rackmount server form factor having a width, a height, and a depth. The server chassis further includes a plurality of front windows in the plane defined by the width and the height. Each front window includes an aperture having a horizontal width and vertical height. The aperture is positioned in a front of the chassis, and defines an opening to one of the window bays. At least two of the apertures define a row of window openings. Each aperture in the row of window openings is arrayed in the direction of the width, and aligned in the vertical height and the horizontal width to each other. Optionally, the number of window openings in the row of window openings is 1 to 10.

In some implementations of the modular server system, the server chassis includes a rackmount server form factor having a width, a height, and a depth. The server chassis further includes a plurality of front windows in the plane defined by the width, and the height. Each front window includes an aperture having a horizontal width and vertical height. The aperture is positioned in a front of the chassis, and defines an opening to one of the window bays. At least two of the apertures define a column of window openings. Each aperture in the column of window openings is arrayed in the direction of the height, and is aligned in the vertical height and the horizontal width to each other. Optionally the number of window openings in the column of window openings is 1 to 10.

In yet other implementations of the modular server system, the server chassis includes a rackmount server form factor having a width, a height, and a depth. The server chassis further includes a plurality of front windows in the plane defined by the width, and the height. Each front window includes an aperture having a horizontal width, and vertical height. The aperture is positioned in a front of the chassis, and defines an opening to one of the window bays. At least two of the apertures define a row of window openings. Each aperture in the row of window openings is arrayed in the direction of the width, and is aligned in the vertical height, and the horizontal width to each other. At least two of the apertures define a column of window openings. Each aperture in the column of window openings is arrayed in the direction of the height, and is aligned in the vertical height and the horizontal width to each other. Optionally, the number of window openings is 3-100.

A second implementation of the disclosure is a device tray for holding a device. The device tray has one or more device slots having interior surfaces defining a space for placement of a device. The device tray also includes a front aperture for slide-in placement of the device; a back aperture for connecting the device to at least a second device; and a fastener for holding the device in the device slot. Optionally, the device tray further has a top including an opening from an outer top surface to the inner top surface. Optionally, the opening is configured as a slit or a round hole. In some implementations, the device tray includes a first part of a fastening mechanism. The device includes a second part of a fastening mechanism. The first part of the fastening mechanism, and the second part of the fastening mechanism, can be engaged when the device is in the device slot. When engaged, the fastening mechanism fastens the device to the device tray. In some implementations, the interior space is defined by at least a top interior surface, a bottom interior surface, and a spacer interior surface.

The implementations according to the disclosure herein provide a unified chassis system that can accommodate different devices. Devices can be easily interchanged in the chassis providing improvements in cost and efficiency to server designs.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims.

### BRIEF DESCRIPTION OF THE DRAWINGS

The disclosure will be better understood from the following description of exemplary embodiments together with reference to the accompanying drawings, in which:

FIG. 1A is a perspective view of an example prior art server chassis with devices installed;

FIG. 1B is a perspective view of a prior art server chassis where a different device cannot be installed;

FIG. 2A is a perspective view of an example unified chassis according to some implementations;

FIG. 2B is a front view of the unified chassis of FIG. 2A;

FIG. 3A is a perspective view of a modular system according to some implementations;

FIG. 3B shows an expanded view of a first module shown in FIG. 3A;

FIG. 3C is a back cross-section view of a device tray shown in FIG. 3B;

FIG. 4 is a perspective view of a modular system according to another implementation;

FIG. 5 is a perspective view of a modular system according to a further implementation;

FIG. 6A is a perspective view of a module according to some implementations of the disclosure;

FIG. 6B shows a locking mechanism for a device in the device tray of FIG. 6A;

FIG. 6C is a back cross-section view of the device tray of FIG. 6A;

FIG. 7A is a top view of the device tray shown by FIG. 6A;

FIG. 7B is a front view of the device tray shown by FIG. 6A;

FIG. 7C is side view or the device tray shown by FIG. 6A;

FIG. 8A is a perspective view of a module according to some implementations of the disclosure;

FIG. 8B is the back cross-section view of a device tray shown in FIG. 8A;

FIG. 9A is a top view of the device tray shown in FIG. 8B;

FIG. 9B is a top view of the device tray shown in FIG. 8B;

FIG. 9C is a side view of the device tray shown in FIG. 8C;

FIG. 10A is a perspective view of a module according to some implementations;

FIG. 10B is a back cross-section view of a device carrier shown in FIG. 10A;

FIG. 10C is a back cross-section view of a device carrier according to another implementation of the device carrier shown in FIG. 10A;

FIG. 11A is a perspective view of a modular system including four modules and a unified chassis according to some implementations;

FIG. 11B is a front view of the unified chassis shown in FIG. 11A;

FIG. 12A is a top schematic view of an implementation of a modular system according to some implementations; and

FIG. 12B is a front schematic view of a modular system according to some implementations of the disclosure.

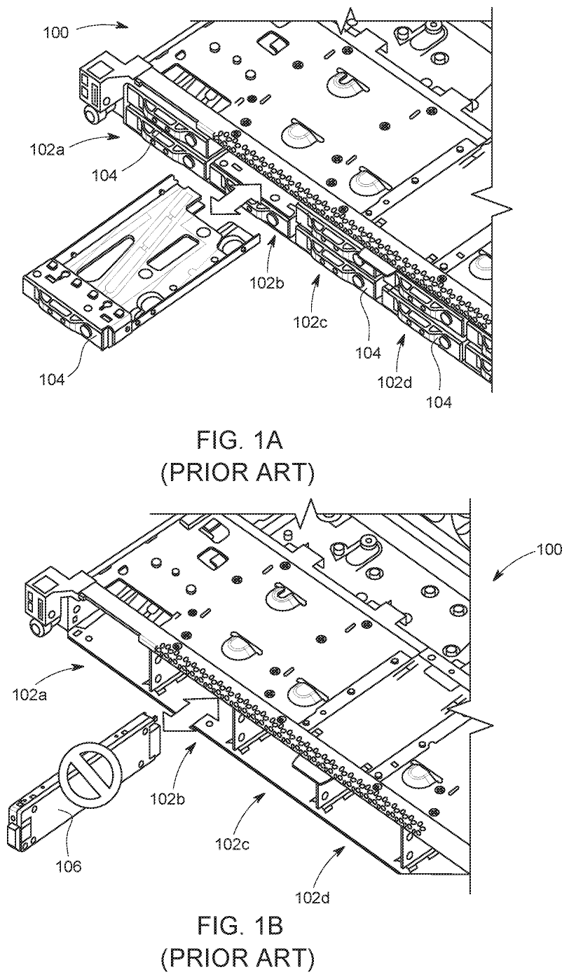

The present disclosure is susceptible to various modifications and alternative forms. Some representative embodiments have been shown by way of example in the drawings and will be described in detail herein. It should be understood, however, that the invention is not intended to be limited to the particular forms disclosed. Rather, the disclosure is to cover all modifications, equivalents, and alternatives falling within the spirit and scope of the invention as defined by the appended claims.

### DETAILED DESCRIPTION

The present inventions can be embodied in many different forms. Representative embodiments are shown in the drawings, and will herein be described in detail. The present disclosure is an example or illustration of the principles of the present disclosure, and is not intended to limit the broad aspects of the disclosure to the embodiments illustrated. To that extent, elements, and limitations that are disclosed, for example, in the Abstract, Summary, and Detailed Description sections, but not explicitly set forth in the claims, should not be incorporated into the claims, singly or collectively, by implication, inference, or otherwise. For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at,” “near,” or “nearly at,” or “within 3-5% of,” or “within acceptable manufacturing tolerances,” or any logical combination thereof, for example.

The present disclosure is directed to a modular server system having one or more front window bays for placement of modules. The modules include a device tray that can hold a device or device carrier. Different modules can carry different devices. For example, in some implementations, the devices have different form factors. The devices can include any device for calculation and storage, such as devices selected from a 3.5 inch HDD, a 2.5 inch HDD, a SSD, a GPU, or a ruler device. Each of the one or more window bays can accept one of any of the different modules.

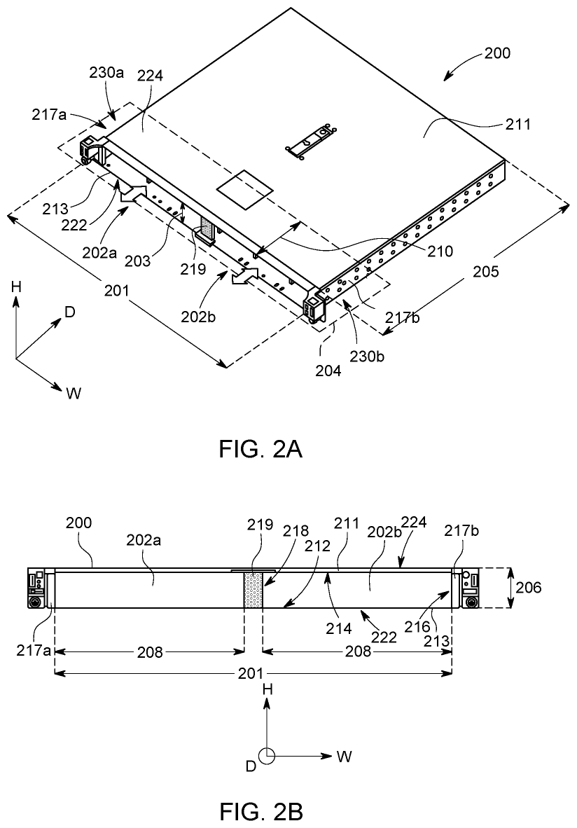

FIG. 2A is a perspective view of a unified server chassis 200 according to some implementations. For orientation, the width W, height H, and depth D directions are indicated. The unified server chassis 200 has a width 201, a height 203, and a depth 205; as defined by a top panel 211, a bottom panel 213, a left side wall 217a, and a right side wall 217b. An outer bottom surface 222, an outer top surface 224, and outer side surfaces 230a, and 230b of the unified server chassis 200 are also indicated. The chassis width 201, height 203, and depth 205 can be any value. For example, in some implementations, values of height 203 can be between 1 and 20 U, 1 and 10 U, or 1 U and 5 U. For example, the unified chassis can have 1, 2, 3, 4, or 5 U as the height 203. The width 201 can be the standard 19 inches, although other widths can be used in the various implementations of an example unified server chassis 200. The depth 205 can be, for example, between about 10 and about 60 inches. In some implementations, the depth 205 is between about 20 and 50 inches, such as about 24, 29, and 48 inches.

The server chassis 200 is dimensioned to fit into a slot of a rack. Thus, the width 201, the height 203, and the depth 205; and, the outer surfaces 222, 224, 230a, and 230b, of the server chassis 200 are configured to fit into a slot of a server rack.

Two window bays 202a, 202b, are shown in a front region 204 (shown by dotted outline). In this example, the window bay, 202a and 202b, have the same dimensions.

FIG. 2B is a front view of the unified server chassis 200, illustrating the window bay 202a, 202b. The window bay 202a, 202b have the same dimensions of a window vertical height 206 and a window horizontal width 208. The window depth 210 (in FIG. 2A) of the window bay 202a, 202b are indicted by a two headed arrow. The window depth 210 is also the same for the window bay 202a, 202b. The window vertical height 206 and the window horizontal width 208 define a window which is an aperture to each of the window bay 202a and 202b.

The window bay 202a, 202b can also be defined by bounding features. The window bay 202a is defined by the top panel 211, a bottom panel 213, the left side wall 217a, and a separator 219. The window bay 202b is defined by the top panel 211, the bottom panel 213, the right side wall 217b, and the separator 219. The bounding features include interior surfaces of the unified server chassis 200. For example, bounding features for the window bay 202b include an inner bottom surface 212, an inner top surface 214, an inner side surface 216, and a separator surface 218. In some implementations, the server chassis 200 can have 1 to 10 window bays, with each having the same dimensions.

As used herein, the “same” dimensions, with respect to the window bay 202a and 202b, refer to the configurations allowing for placement, and optionally securing of a device tray in either of window bay 202a or 202b. For example, a device tray has an outer surface and features commensurate with the inner surfaces and features defining the window bays 202a and 202b. In some implementations, the outer surfaces of the device can include a rail, and the window bay 202a, 202b include a groove as part of an inner surface. The grove engages the rail when the device is inserted in the window bay 202a, 202b. In some implementations, the outer surface of the device includes a groove, while the inner surface of the window bay 202a, 202b include a rail. The rail engages the groove when the device is inserted in the window bay 202a, 202b. The groove and rail features can aid in guiding and placement of a device tray in the window bay 202a, 202b. In some implementations, a device tray may have features, such as nubs, where the window bay 202a, 202b have commensurate features of an indentation for the nubs. Alternatively, or additionally, a device tray may have an indentation where the window bay 202a, 202b can have a nub. Other features, such as extenders, holders, or fasteners from a device tray to an inner surface defining the window bay 202a, 202b can also be used. Alternatively, features such as extenders included in the window bay 202a, 202b can extend to a device tray to hold or guide placement of the device tray in the window bay 202a, 202b. For example, features can be mounted on, attached to, or form part of, one or more of the inner bottom surface 212, the inner top surface 214, the inner side surface 216, or the separator surface 218. The features in the window bay 202a, 202b are also included in the definition of the one or more window bays each having the same dimensions as used herein.

In some implementations, a device tray can have a height about equal to the window vertical height 206, and the device tray can have a width about equal to the window horizontal width 208. In these implementations, the device tray can be about the same or less than the window depth 210. For example, the depth of the device in some implementations is as at least 10% less than, at least 20% less than, at least 30% less than, at least 40% less than, or at least 50% less than the window depth 210.

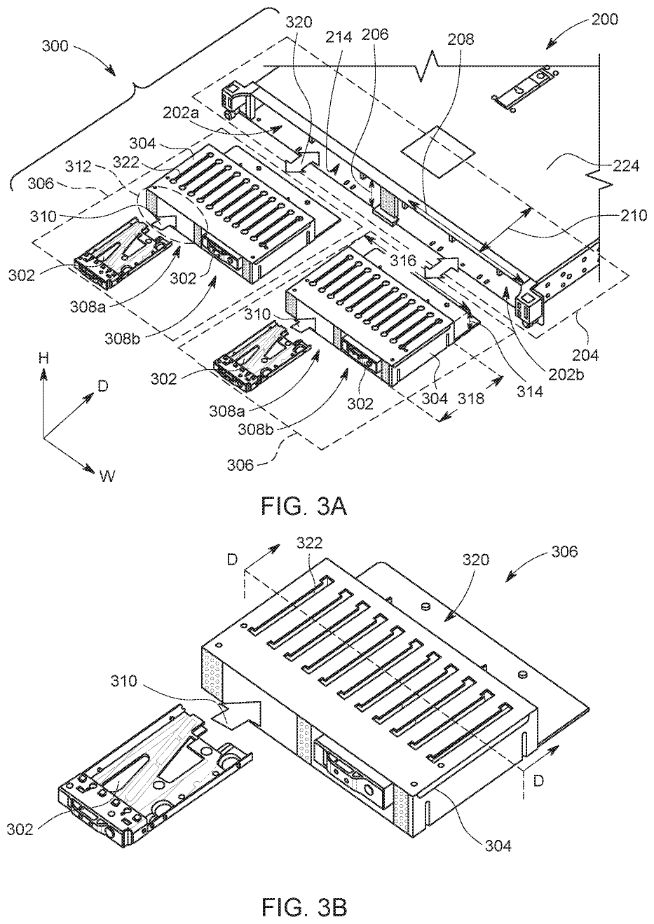

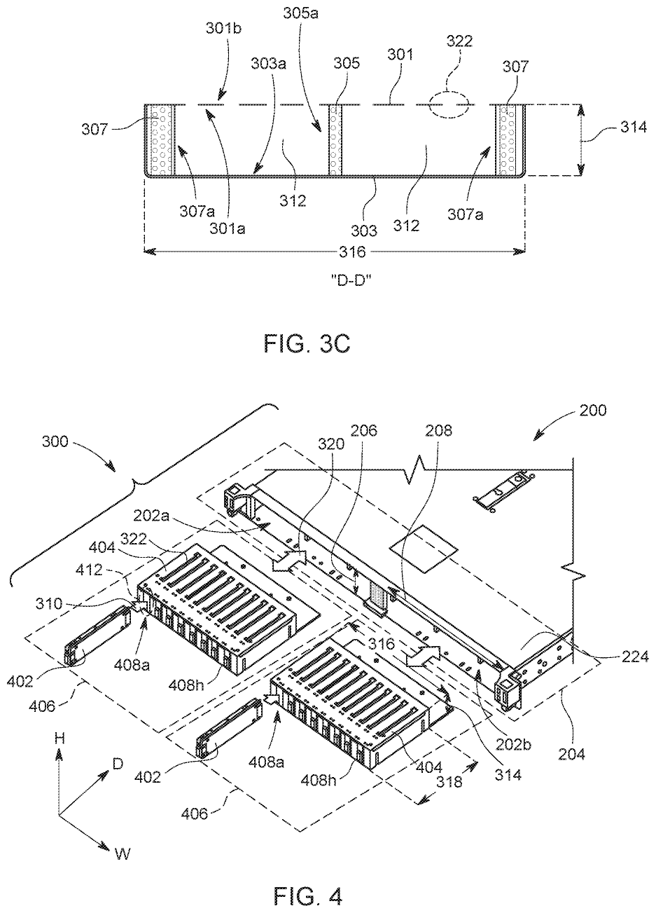

FIG. 3A is a perspective view of a modular system 300 according to some implementations. The modular system 300 includes the unified server chassis 200, a first device tray 304, and a first device carrier 302. The combination of the first device tray 304 and first device carrier 302 form a first module or subsystem 306. The first device tray 304 is configured to hold one or two of the first device carriers 302 in each first module 306.

In some implementations, the modular system 300 includes a device (not shown in FIG. 3A) which is held by a device carrier, such as the first device carrier 302. Any device having a matching form factor to the device carrier 302 can be used. For example, in the implementation shown by FIG. 3A, the first device carrier 302 is for a 2.5 inch HDD. Accordingly, in some implementations, the first module 306 can include a device, the first device carrier 302, and the first device tray 304. In some other implementations the first module 306 includes only the first device carrier 302.

The first device tray 304 includes two device slots 308a and 308b for placement of the first device carrier 302. The device slot 308a is shown unoccupied, that is, without a device carrier, such as the first device carrier 302 in the device slot 308a. A large arrow 310 illustrates slide-in placement. A first device carrier 302 slides into the first device tray 304 through the outlined aperture 312. This places the first device carrier 302 into the device slot 308a. A first device carrier 302 is shown occupying the device slot 308b.

Although referred to as “slide-in placement,” reversal of the steps can be used to remove a device or device carrier from a device tray, and to remove a device tray from a window bay. For example, the slide-in placement steps can be reversed to remove the first device carrier 302 from the device slot 308b.

The first device tray 304 can be placed into either of the window bays 202a or 202b of the unified server chassis 200. This is because the first device trays 304 have outer dimensions similar to the dimensions of the window bay 202a, 202b. For example, a device tray height 314 can be about the same as the window vertical height 206. A device tray width 316 can be about the same as the window horizontal width 208. A device tray depth 318 can be about the same as or shorter than the window depth 210 of the window bay 202a, 202b.

FIG. 3B shows an expanded view of the module 306. A cross-section plane “D-D” is shown. An aperture 320 at the back of first device tray 304 is also shown. FIG. 3C is the back view of the cross section “D-D” in FIG. 3B, and does not show the first device carrier 302 in the device slots 308a or 308b (both in FIG. 3A). The first device tray 304 has a top 301, a bottom 303, a separator 305, and side walls 307. The device slots 308a and 308b have interior surfaces that define a space for placement of the device. The top 301 provides a top inner surface 301a. The bottom 303 provides a bottom inner surface 303a. The separator 305 provides an inner surface 305a. The side walls 307 provide an inner surface 307a. The device slots 308a and 308b are also defined by at least one aperture 312 in the front of first device tray 304. One or more apertures 320 in the back of the first device tray 304 allows for electrical connections from devices placed in the first device carrier 302, to other components mounted in the unified server chassis 200. For example, electrical connections may be made to a mother board and a power supply.

In some implementations, the first device trays 304 have additional features on their surfaces. For example, as illustrated by FIGS. 3A-3C, the first device trays 304 include a slot feature 322. In this implementation, the feature is on the top 301, and is configured as a slot providing an opening from the top outer surface 301b to the top inner surface 301a. In other implementations, the features can be a round or other shaped opening. Such features can, for example, provide ventilation, reduce the weight of a device carrier, or increase flexibility of a device carrier. In some implementations, such features can provide a coupling function, such as to a matching feature on the inner top surface 214 of the unified server chassis 200, or to a matching feature on a device or a device carrier. In some other implementations, such features can be for assembly purposes, such as screw holes. Other features can be used, such as rails and other protrusions, such as those mounted on or as a part of the top 301.

In some implementations, the first device tray 304 is placed in the window bay 202a or 202b by slide-in placement, as shown by a large arrow 310. The first device tray 304 slides into the window openings defined by the window vertical height 206 and the window horizontal width 208. This slide-in placement places the first device tray 304 in the window bay 202a or 202b.

In other implementations, one or more of the walls defining the unified server chassis 200 can be removed. For example, at least a portion of the wall defined by the outer top surface 224 and the inner top surface 214 can be removed to allow placement of the first device tray 304 in the window bay 202a or the window bay 202b.

FIG. 4 is a perspective view of the modular system 300 according to another implementation. The modular system 300 includes the unified server chassis 200, a second device 402, and a second device tray 404. The combination of the second device tray 404 and the second device 402 form a second module or subsystem 406. In this embodiment, the second device tray 404 is configured to hold up to eight of the second devices 402 in each second module 406.

In some implementations, the modular system 300 includes a second device carrier for the second device 402. Any device having a matching form factor to the second device carrier can be used in the modular system 300. For example, in the implementation shown by FIG. 4, the device 402 has a ruler form factor.

The second device tray 404 includes eight slots 408a-408h. For clarity, only the device slots 408a and 408h are indicated. The slots, such as device slots 408a and 408h, are configured for placement of the second device 402 in the second device tray 404. The device slot 408a is shown unoccupied by a device.

A large arrow 310 illustrates how a slide-in placement of the second device 402 into the second device tray 404, through the outlined aperture 412, can place the second device 402 into the device slot 408a. A second device 402 is shown occupying the device slot 408h.

The second device tray 404 can be placed into any one of the window bays 202a, 202b of the unified server chassis 200. This is because the second device trays 404 have outer dimensions similar to the dimensions of the window bay 202a, 202b. The second device trays 404 also have outer dimensions similar to the outer dimensions of the first device trays 304 (FIG. 3A). For example, the second device tray height 314 can be about the same as window vertical height 206. The device tray width 316 can be about the same as the window horizontal width 208. The second device tray depth 318 can be about the same as or shorter than the window depth 210 of the window bays 202a and 202b.

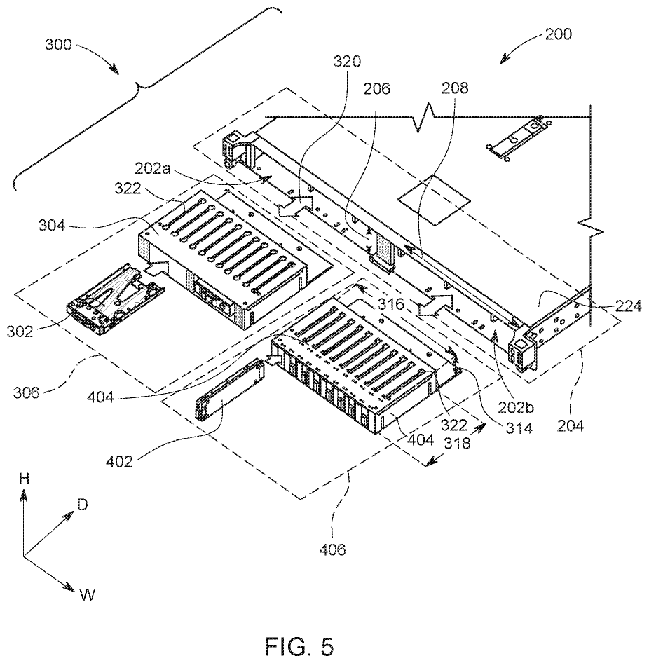

FIG. 5 is a perspective view of yet another implementation of the modular system 300. The modular system 300 in this implementation includes the unified server chassis 200, the module or subsystem 306, and the module or subsystem 406. The first device tray 304 and the second device tray 404 can each be placed in one of the window bays 202a, 202b. The first device tray 304 can be placed into the window bay 202a, and the second device tray 404 can be placed into the window bay 202b. Optionally, the first device tray 304 can be placed into the window bay 202b, and the second device tray 404 can be placed into the window bay 202a. The placement of the first device tray 304 and the second device tray 404 into either the window bay 202a or 202b is interchangeable because the window bays 202a and 202b have the same dimensions, as previously described.

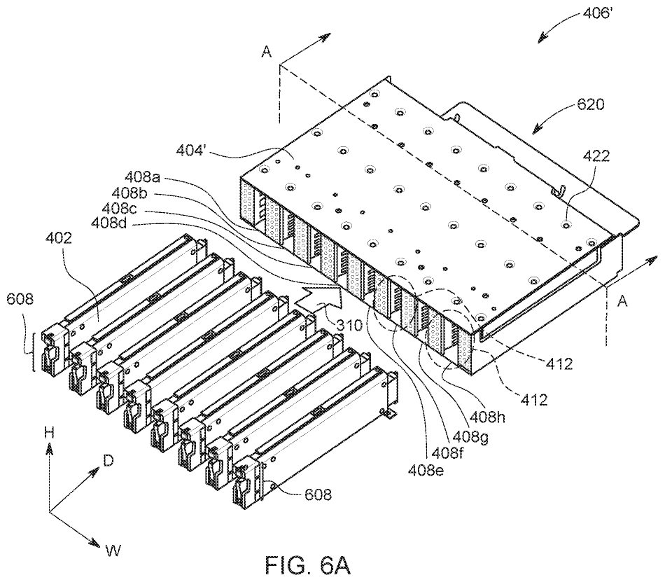

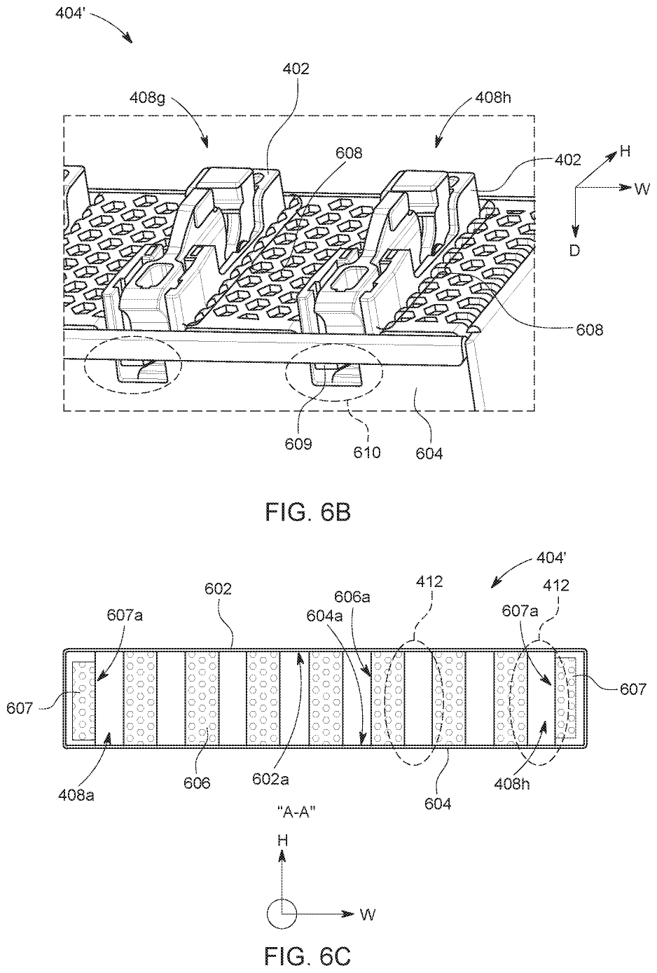

FIG. 6A shows a perspective view of a module or subsystem 406′ that includes a device tray 404′, according to some implementations of the disclosure. The device tray 404′ is similar to the device tray 404, shown in FIG. 4. Some differences are shown, for example FIGS. 4 and 5 shows slot features 322, while round hole features 422 are included in the device tray 404′. The hole features 422 can be provided for assembly purposes, such as for accepting a screw or other fasteners. The hole features 422 can also be for other purposes as previously described, such as for ventilation, weight management, and providing flexibility. The device tray 404′ is configured for slide-in placement of the second devices 402, into the device slots 408a to 408h, as indicated by the large arrow 310.

An aperture 620 in the back of device tray 404′ allows for electrical connections from the second devices 402 to other components mounted in the unified server chassis 200. For example, electrical connections can be made to a mother board and a power supply through the aperture 620.

Each of second devices 402 has the same form factor. In this example, there are eight second devices 402 that fit in the corresponding device slots 408a to 408h. As used herein, a “member” is a single device in a group of devices. In some other implementations, a device tray can include more or less positions for holding devices. For example, the group of devices can have 1 to 20, or 1 to 10, or 1 to 8, or 1 to 2 members. A fastener 608 of the device 402 is shown in FIG. 6A, and also in blown-up and reoriented view FIG. 6B. In some implementations, the fastener 608 is part of a carrier for device 402.

FIG. 6B is a bottom-up view of portions of the second devices 402 inserted in the device slots 408a and 408b of the device tray 404′. The fastener 608 is included as a part of the second device 402, or when used, a carrier for the second device 402. The fastener 608 includes a first part of a latching mechanism 609 that engages a second part of a latching mechanism 610, which is an opening of a bottom 604 of the device tray 404′. By engaging the first latching mechanism 609 with the second latching mechanism 610, the second device 402 is secured in its respective slot, such as in one of the device slots 408g and 408h. Other implementations use other methods to fix devices, such as the second devices 402 in device carriers. For example, the other methods may include snap in placement, friction, or clamping.

FIG. 6C is the back view of the cross section “A-A” in FIG. 6A. The device tray 404′ has a top 602, a bottom 604, separators 606, and side walls 607. The device slots 408a and 408h are defined by inner surfaces of the top 602, the bottom 604, the separators 606, and the side walls 607. The device slots 408a and 408h are defined by inner surfaces of the top 602, the bottom 604, and the separators 606. The top 602 provides the inner surfaces 602a. The bottom 604 provides the inner surfaces 604a. The separators 606 provide the inner surfaces 606a. The side walls 607 provide the inner surfaces 607a. Each device slot 408a to 408h is also defined by at least one aperture 412 in the front of device tray 404′.

In some implementations, the device tray 404′ is symmetrical from left to right and top to bottom as viewed from the front, as shown in FIG. 6A. In other implementations, the device trays are symmetrical from left to right but not top to bottom. The device trays can also be symmetrical from top to bottom but not left to right, or not symmetrical on all four sides as viewed from the front.

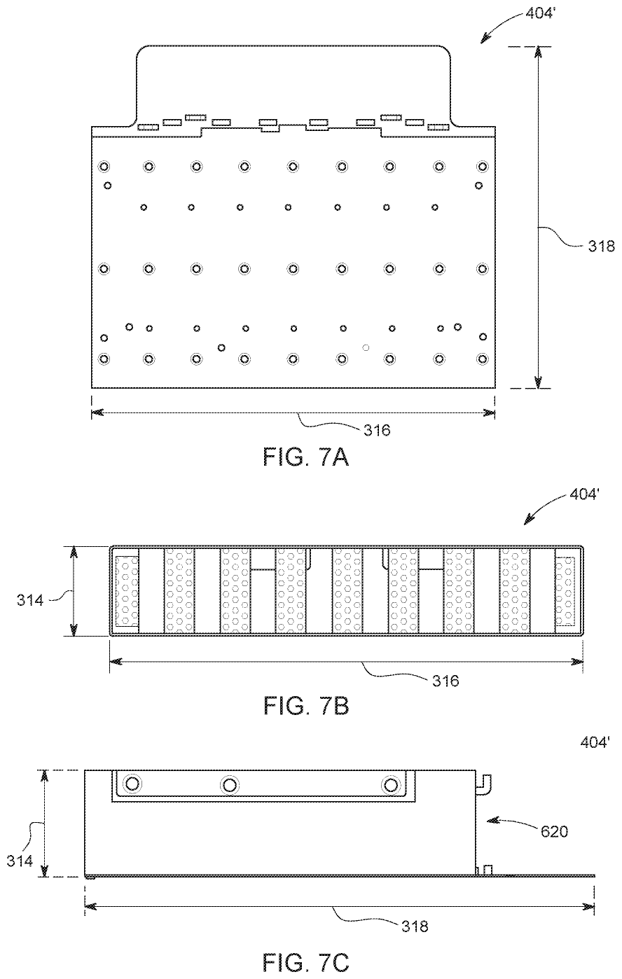

FIG. 7A shows a top view of the device tray 404′. FIG. 7B shows a front view of device tray 404′. FIG. 7C shows a side view of device tray 404′. The device tray height 314, the device tray width 316, and the device tray depth 318 are shown. The window vertical height 206 of the window bays 202a, 202b (e.g., shown in FIG. 5) is about the same as the device tray height 314 of the device tray 404′. The window horizontal width 208 (FIG. 5) is about the same as the device tray width 316. The window depth 210 (FIG. 5) is about the same as the device tray depth 318.

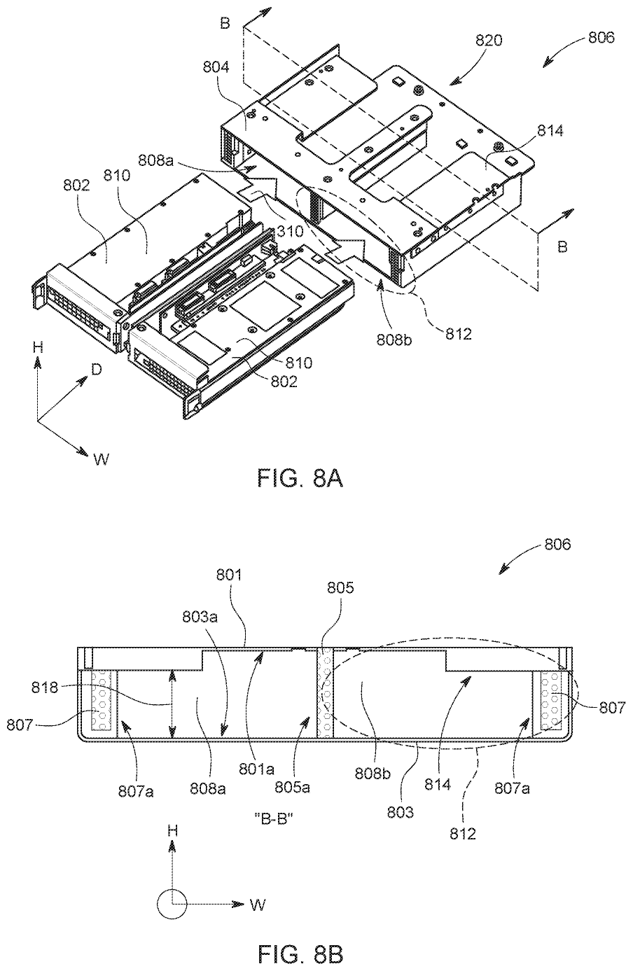

FIG. 8A shows a perspective view of a third module or subsystem 806 according to some implementations of the disclosure. The third module 806 includes a third device tray 804, and third devices 802. The third devices 802 can also include a third device carrier. The third devices 802, or a third device carrier for the devices 802, are configured for slide-in placement into device slots 808a and 808b. The device slots 808a, 808b are also defined by at least one aperture each 812 in the front of the third device tray 804.

An aperture 820 in the back of the third device tray 804 allows for insertion of cables for electrical connections to other components installed in the unified server chassis 200.

Each of the third devices 802 has the same form factor. The devices 802 form a group of two member devices that fit in the device slots 808a and 808b. In this implementation, the device is a Graphics Processing Unit (GPU) card, but other devices may be used.

FIG. 8B is the back view of the cross section “B-B” in FIG. 8A. The third device tray 804 has a top 801, a bottom 803, a separator 805, and side walls 807. The device slots 808a and 808b are defined by inner surfaces of the top 801, the bottom 803, the separator 805, and the side walls 807. The top 801 provides inner surfaces 801a. The bottom 803 provides inner surfaces 803a. The separator 805 provides inner surfaces 805a. The side walls 807 provide inner surfaces 807a.

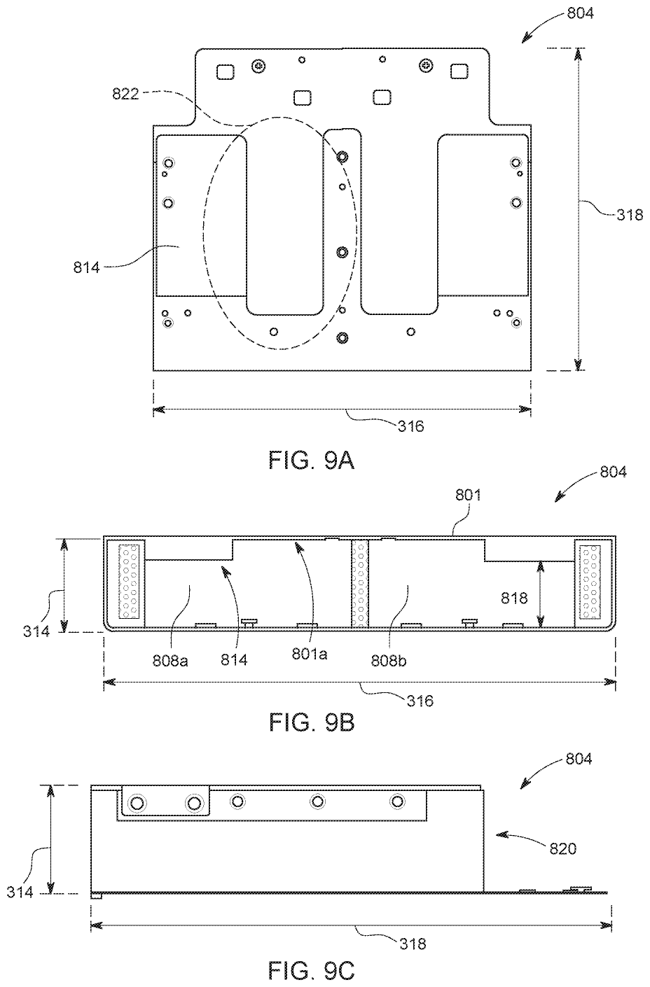

FIG. 9A shows a top view of the third device tray 804. FIG. 9B shows a front view of the third device tray 804. FIG. 9C shows a side view of the third device tray 804. The third device tray height 314, the third device tray width 316, and the third device tray depth 318 are shown. The window vertical height 206 (e.g., shown in FIG. 5) is about the same as the third device tray height 314 of the third device tray 804. The window horizontal width 208 (FIG. 5) is about the same as the third device tray width 316. The window depth 210 (FIG. 5) is about the same as the third device tray depth 318.

The third device tray 804 has a large open slot feature 822 formed on the top 801. In some implementations, the open slot feature 822 is provided for matching the form factor shape of the third device 802 (shown in FIG. 8A). The open slot feature 822 can also be provided for purposes as previously described, such as for ventilation, weight management, and providing flexibility.

In the implementation illustrated by FIGS. 8A and 9B, the inner surface 801a includes a feature 814 formed as part of the top 801. The feature 814 reduces an interior device holder height distance 818 as compared to the third device tray height 314. The feature 814 can provide contact with the top surface 810 of the device 802 (shown in FIG. 8A), and accommodates the form factor of the third device 802. This feature also provides a space to accommodate connecting cables.

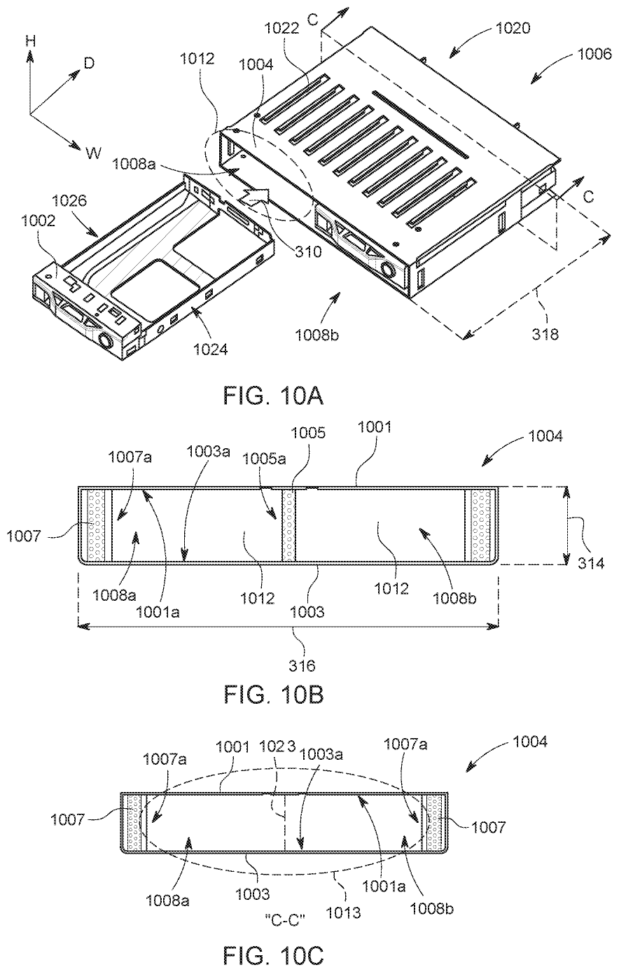

FIG. 10A shows a perspective view of a fourth module or subsystem 1006, according to some implementations of the disclosure. The fourth module 1006 includes a fourth device tray 1004 and a fourth device carrier 1002. In this implementation, the fourth device carrier 1002 is configured for holding a 3.5 inch HDD. The fourth device carrier 1002, or the fourth device and the fourth device carrier 1002, is configured for slide-in placements, shown by the large arrow 310, into device slot 1008a, 1008b of the fourth device carrier 1002. An aperture 1020 in the back of fourth device tray 1004 allows for electrical connections to other components installed in the unified server chassis 200. The slot features 1022 are provided for reasons as previously described, e.g., to improve ventilation, save material costs, provide wall flexibility or reduce overall weight of fourth device tray 1004.

FIG. 10B is a back view of the cross section “C-C” in FIG. 10A. The fourth device tray 1004 has a top 1001, a bottom 1003, a separator 1005, and side walls 1007. Device slots 1008a and 1008b are defined by inner surfaces of the top 1001, the bottom 1003, the separator 1005, and the side walls 1007. The top 1001 provides inner surfaces 1001a. The bottom 1003 provides inner surfaces 1003a. The separator 1005 provides inner surfaces 1005a. The side walls 1007 provide inner surfaces 1007a. The device slots 1008a are 1008b are also defined by apertures 1012 in the front of the device tray 1004.

In some implementations, one or more features of device trays as described herein can be removed, missing, or modified without altering the functioning of the device tray. For example, FIG. 10C shows an alternative implementation of the third device tray 1004 from the view of the cross section “C-C” in FIG. 10A. In this embodiment, the separator 1005 shown in FIG. 10B is removed. The aperture 1013 is defined by the inner surfaces 1001a, 1003a, and 1007a, and accordingly is at least twice the size as the two apertures 1012 in FIG. 10B. A boundary 1023, shown as a dotted line, indicates a subdividing boundary for defining the device slot 1008a and 1008b. In this implementation, the device slots 1008a and 1008b are defined by an inner surface 1001a, an inner surface 1003a, an inner surface 1007a, and the boundary 1023. The boundary 1023 is provided by the third device carrier 1002 (Shown in FIG. 10a). For example, as shown in FIG. 10a, a surface 1024 of the third device carrier 1002 in the device slot 1008a, and a surface 1026 of the device carrier 1002 in the device slot 1008b form the boundary 1023.

The fourth device tray 1004 is configured to fit into the window bays 202a, 202b (e.g., shown in FIG. 5) of the unified server chassis 200. The fourth device tray height 314, the fourth device tray width 316, and the fourth device tray depth 318 are shown in FIGS. 10A and 10B. The window vertical height 206 of the window bays 202a and 202b are about the same as the fourth device tray height 314 of fourth device tray 1004. The window horizontal width 208 is about the same as the fourth device tray width 316. The window depth 210 is about the same as the fourth device tray depth 318.

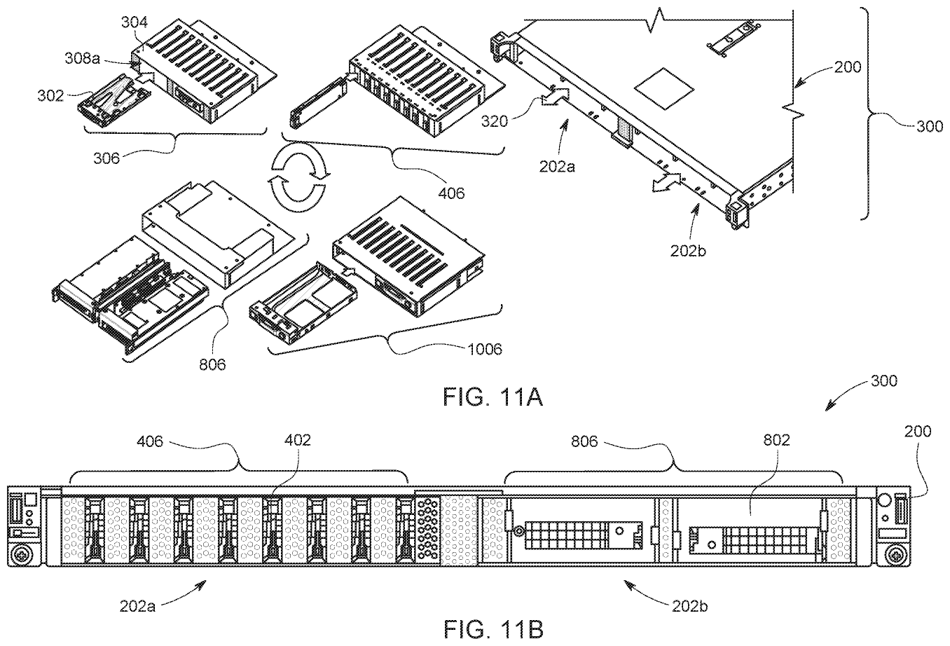

FIG. 11A shows the modular system 300 according to another implementation. The first module 306, second module 406, third module 806, fourth module 1006, and the unified server chassis 200 are shown as a perspective view. Any one or two of first module 306, second module 406, third module 806, and fourth module 1006 can be placed in the window bays 202a or 202b of the modular system 300.

FIG. 11B shows a front view of the unified server chassis 200 with two modules and corresponding devices in place. The second module 406 and the second device 402 (ruler device) are shown in window bay 202a on the left. The third module 806 and the third devices 802 (GPU) are shown in the window bay 202b on the right.

In some implementations for assembling a unified server system, a device tray is first inserted in the window bay 202a or 202b, and then a corresponding device is placed in the device tray. For example, the first device tray 304 is placed in one of the window bays 202a or 202b, and then a device and the first device carrier 302 (FIG. 11A) are placed in the device slot 308a of the first device tray 304. Alternatively, in some implementations, a device is placed in a device tray, and then the device tray holding the device is placed in the window bay 202a or 202b.

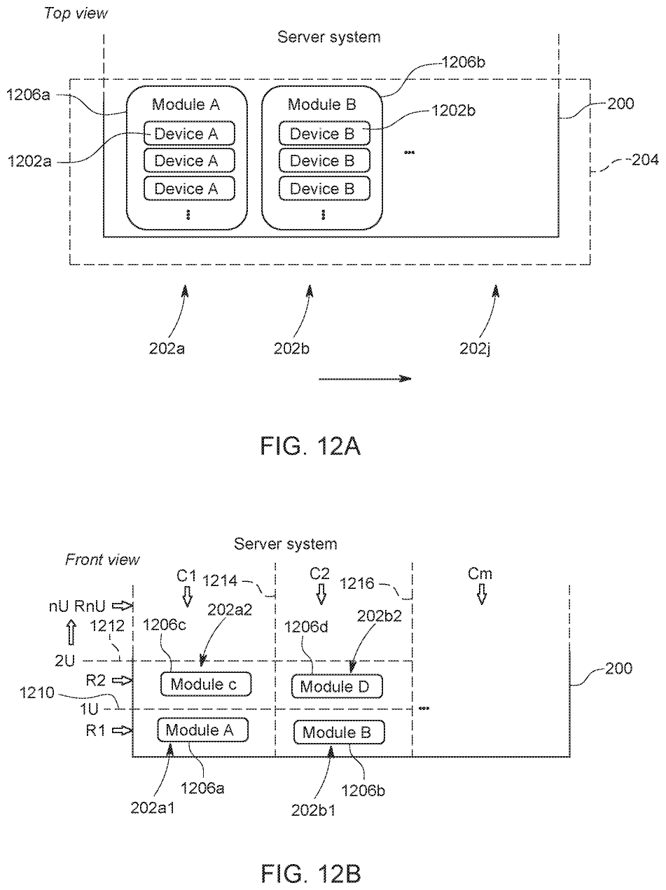

FIG. 12A is a top schematic view of a modular system, according to some implementations. A first module (Module A) 1206a and a second module (Module B) 1206b are placed in a front region 204 of the unified server chassis 200. The module 1206a is shown in the window bay 202a. The module 1206b is shown in the window bay 202b. As indicated, the unified server chassis 200 can have two or more window bays 202a and 202b in a row. For example, the unified chassis can have between 1 to 10 window bays 202a-202j.

Each of the modules shown in FIG. 12A can also have one or more devices. For example, the module 1206a can have one or more devices, such as a device (Device A) 1202a. The module 1206b can have one or more devices, such as a device (Device B) 1202b. As previously described, there may be any number of devices, for example, in some implementations 1-20 members.

FIG. 12B is a front schematic view of a modular system, according to some implementations. The modules (Module A) 1206a, (Module B) 1206b, (Module C) 1206c, and (Module D) 1206d are shown. The modules 1206a, 1206b, 1206c, and 1206d are shown arranged in rows and columns. Rows are denoted as R1, R2 to Rn. In this embodiment, each row has a width of one rack unit (U), and the “n” denotes the number of rows. In other embodiments, the rows can be other widths such, as each being 2 U, 3 U, 4 U, or 5 U. The number of rows depends on the row width and unified chassis height. In some implementations, the number of rows is 1 to 20, 1 to 10, 1 to 5 or 1 to 2. The columns are denoted as C1, C2 to Cm, where m is the number of columns. The number of columns can be any value. For example, 1 to 20, 1 to 10, 1 to 5, or 1 to 2.

In some implementations the modules are aligned in rows. Thus, the top (or bottom) of the module 1206a aligns with the top (or bottom) of the module 1206b. For example, a top alignment line for R1 is a dashed line 1210 at a 1 U height. This is provided by corresponding row alignment of the window openings of the window bays 202a1, 202a2, 202b1, and 202b2. Similarly, the module 1206c and the module 1206d can be aligned in row 2 (R2). A top alignment line for row R2 is a dashed line 1212 at the 2 U height.

In some implementations, the modules are aligned in columns. For example, the side of the module 1206a is aligned with the corresponding side of the module 1206c. The side of the module 1206b is aligned to the side of the module 1206d. A dashed line 1214 shows the alignment of column C1, and a dashed line 1216 shows the alignment of column C2. The alignment of the columns is provided by a corresponding alignment of window openings of the window bays 202a1, 202a2, 202b1, and 202b2. The window bays 202a1, 202a2, 202b1, and 202b2 have similar characteristics as previously described for window bays 202a, 202b (e.g., shown in FIG. 5).

The terminology used herein is for the purpose of describing particular embodiments only, and is not intended to be limiting of the invention. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art. Furthermore, terms, such as those defined in commonly used dictionaries, should be interpreted as having a meaning that is consistent with their meaning in the context of the relevant art, and will not be interpreted in an idealized or overly formal sense unless expressly so defined herein.

While various embodiments of the present invention have been described above, it should be understood that they have been presented by way of example only, and not limitation. Numerous changes to the disclosed embodiments can be made in accordance with the disclosure herein, without departing from the spirit or scope of the invention. Thus, the breadth and scope of the present invention should not be limited by any of the above described embodiments. Rather, the scope of the invention should be defined in accordance with the following claims and their equivalents.

Although the invention (disclosed embodiments) has been illustrated and described with respect to one or more implementations, equivalent alterations, and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

1. A modular server system comprising:
a server chassis having one or more window bays each having the same dimensions; and
a first device tray having exterior dimensions fitting in any of the one or more window bays and a first set of interior features for holding a plurality of first storage devices, each having a first type of form factor; and
a second device tray having exterior dimensions fitting in any of the one or more window bays and interchangeable with the first device tray, the second device tray having a second set of interior features for holding a plurality of second graphics processor unit devices, each having a second type of form factor, the second type of form factor different from the first type of form factor.

2. (canceled)

3. The system of claim 1, wherein the first device is a member of a group of devices held by the first device tray, each device in the group of devices having the same form factor.

4. The system according to claim 1, wherein the first device tray includes a device carrier for coupling the first device with the first device tray.

5. The system according to claim 1, wherein the first devices are selected from a hard disk drive (HDD), a solid state drive (SSD), and a ruler device.

6. The system of claim 1, wherein the first device tray comprises:
one or more device slots having interior surfaces defining an interior space for placement of the first device;
a front aperture for slide-in placement of the first device;
a back aperture for electrically connecting the first device to a component in the server chassis; and
a fastener for holding the first device in the device slot.

7. The system of claim 6, wherein the interior space is defined by at least:
a top interior surface;
a bottom interior surface; and
a spacer interior surface.

8. The system according to claim 1, wherein each of the window bays comprise:
a window horizontal width accommodating a device tray width of the first device tray, a window vertical height accommodating a device tray height of the first device tray, and a window depth accommodating a device tray depth of the first device tray; and
an aperture in the chassis defined by the window horizontal width and window vertical height, the aperture allowing slide-in placement of the first or second device trays in each of the window bays by engagement of one or more of an inner surface defining the window bay, a rail of the window bay, a groove of the window bay, and a fastener of the window bay.

9. (canceled)

10. The system according to claim 1, wherein the server chassis comprises:
a rackmount server form factor comprising a width, a height, and a depth; and
a plurality of front windows in a plane defined by the width and the height;
each front window comprising:
an aperture having a horizontal width and a vertical height, and wherein the aperture is positioned in a front of the chassis and defines an opening to one of the window bays;
wherein at least two of the apertures define a row of window openings, and each aperture in the row of window openings is arrayed in a direction of the width and aligned in the vertical height and the horizontal width to each other.

11. The system according to claim 10, wherein the number of window openings in the row of window openings is 1 to 10.

12. The system according to claim 1, wherein the server chassis comprises:
a rackmount server form factor comprising a width, a height, and a depth; and
a plurality of front windows in a plane defined by the width and the height of the rackmount server form factor;
each front window comprising:
an aperture having a horizontal width and a vertical height, and wherein each aperture is positioned in a front of the chassis and defines an opening to one of the window bays;
wherein at least two apertures define a column of window openings, and each aperture in the column of window openings is arrayed in a direction of the height and aligned in the vertical height and the horizontal width to each other.

13. The system according to claim 12, wherein the number of window openings in the column of window openings is 1 to 10.

14. The system according to claim 1, wherein the server chassis comprises:
a rackmount server form factor comprising a width, a height, and a depth; and
a plurality of front windows in the plane defined by the width and the height of the rackmount server form factor;
each front window comprising:
an aperture having a horizontal width and a vertical height, and
each aperture positioned in a front of the chassis and defining an opening to one of the window bays;
wherein at least two of the apertures define a row of window openings, and each aperture in the row of window openings is arrayed in the direction of the width and aligned in the vertical height and the horizontal width to each other; and
wherein at least two of the apertures define a column of window openings, and each aperture in the column of window openings is arrayed in a direction of the height and aligned in the vertical height and the horizontal width to each other.

15. The system according to claim 14, wherein the number of window openings is 3-100.

16-20. (canceled)
